(19) United States
(12) Patent Application Publication
(10) Pub. No.: US 2024/0363503 A1
(43) Pub. Date: Oct. 31, 2024

(54) SEMICONDUCTOR DEVICES WITH DOUBLE-SIDED FANOUT CHIP PACKAGES

(71) Applicant: Avago Technologies International Sales Pte. Limited, Singapore (SG)

(72) Inventors: Dingyou Zhang, San Jose, CA (US); Li Sun, San Jose, CA (US)

(21) Appl. No.: 18/309,308

(22) Filed: Apr. 28, 2023

(51) Int. Cl. H01L 23/495; H01L 23/00; H01L 23/498

(52) U.S. Cl. CPC H01L 23/49575; H01L 23/4952; H01L 23/49827; H01L 24/09; H01L 24/49; H01L 2224/0903; H01L 2224/09102; H01L 2224/4903; H01L 2224/49107; H01L 2224/49421

(57) ABSTRACT

The present invention relates to semiconductor devices and integrated circuit packaging. In a specific embodiment, a semiconductor device comprising a double-sided fanout die package is provided. On one surface of a main circuit board for the semiconductor device, regular single-sided flip-chip dies and tall SMT components are coupled, along with one or more double-sided fanout dies, which are stacked with corresponding sub-sized circuit boards that are also coupled to the same surface, with a smaller height than the tallest surface mount device. A portion of the metal routing and grounding connections in the main circuit board for one or more double-sided fanout dies can be transferred to the sub-sized circuit boards, thereby reducing the area of the main circuit board without increasing the number of circuit board layers. There are other embodiments as well.

### FIELD

The present invention is directed to semiconductor devices and integrated circuit packaging.

### BACKGROUND OF THE INVENTION

Semiconductor fan-out device packaging is a modern packaging technology used in the manufacturing of integrated circuits (ICs). It is an advanced version of traditional packaging methods, designed to meet the growing demand for high-performance and compact electronic devices. Fan-out device packaging offers several advantages over traditional packaging methods, including higher levels of integration, improved thermal performance, and smaller form factors. The technology involves distributing the I/O (input/output) pads of the IC across the package substrate, enabling multiple dies to be stacked and interconnected in a single package. This results in more efficient use of the package real estate and a reduction in the overall size of the packaged device. The high level of integration offered by fan-out device packaging is particularly important for applications such as mobile devices, where space is at a premium, and high performance is required.

In today's double-sided module, the limited space for metal routing and grounding within the PCB layers is the major constraint for reducing the overall size and number of layers in the PCB, hindering further reductions in both the x and y lateral dimensions of the module and limiting reductions of module height in the z dimension. Traditional methods cannot achieve further reductions in module size and height without compromising its functionality. Therefore, new devices based on double-sided fanout chip packaging and methods are proposed.

### BRIEF DESCRIPTION OF THE DRAWINGS

A further understanding of the nature and advantages of particular embodiments may be realized by reference to the remaining portions of the specification and the drawings, in which like reference numerals are used to refer to similar components. In some instances, a sub-label is associated with a reference numeral to denote one of multiple similar components. When reference is made to a reference numeral without specification to an existing sub-label, it is intended to refer to all such multiple similar components.

FIG. 1 is a simplified diagram to illustrate an approach for packaging a double-sided semiconductor module.

FIG. 2 is a simplified diagram to illustrate a double-sided semiconductor module according to embodiments of the present invention.

FIG. 3 a simplified diagram to illustrate a process flow of forming double-sided chip package according to an embodiment of the present invention.

FIG. 4 is a simplified diagram to illustrate a double-sided semiconductor module according to another embodiment of the present invention.

FIG. 5 is a simplified diagram to illustrate a double-sided semiconductor module according to yet another embodiment of the present invention.

FIG. 6 is a simplified diagram to illustrate a double-sided semiconductor module according to still another embodiment of the present invention.

FIG. 7 is a simplified diagram to illustrate a double-sided semiconductor module according to yet still another embodiment of the present invention.

FIG. 8 is a simplified diagram to illustrate a double-sided semiconductor module according to further another embodiment of the present invention.

### DETAILED DESCRIPTION OF THE INVENTION

The present invention relates to semiconductor devices and integrated circuit packaging. In a specific embodiment, a semiconductor device comprising a double-sided fanout chip package is provided. On one surface of a main circuit board for the semiconductor device, regular single-sided flip-chip dies and tall surface mounted components are coupled, along with one or more double-sided fanout chips, which are stacked with corresponding sub-sized circuit boards that are also coupled to the same surface, with total stacked height near the height of the tallest surface mounted components. A portion of the metal routing and grounding connections in the main circuit board can be transferred to the sub-sized circuit boards, thereby reducing the area of the main circuit board without increasing the number of circuit board layers. There are other embodiments as well.

In the following description, for the purposes of explanation, numerous details are set forth to provide a thorough understanding of the described embodiments. It will be apparent to one skilled in the art, however, that other embodiments may be practiced without some of these details. Several embodiments are described herein, and while various features are ascribed to different embodiments, it should be appreciated that the features described with respect to one embodiment may be incorporated with other embodiments as well. By the same token, however, no single feature or features of any described embodiment should be considered essential to every embodiment of the invention, as other embodiments of the invention may omit such features.

For example, the term “circuit board”, including the mentioned “main circuit board” and “sub-sized circuit board”, also known as a printed circuit board (PCB), refer a flat, rigid board made of insulating material, typically fiberglass or plastic, that contains a complex network of metallic pathways, or “traces,” that form the electrical circuitry for various electronic devices. Components such as resistors, capacitors, and integrated circuits are then mounted onto the board, and their leads are soldered onto the corresponding traces to create a functioning electronic circuit. “Main” or “sub-sized” is mainly referring to a lateral size of the circuit board, which is one of focal features of the present disclosure.

When an element is referred to herein as being “connected” or “coupled” to another element, it is to be understood that the elements can be directly connected to the other element or have intervening elements present between the elements. In contrast, when an element is referred to as being “directly connected” or “directly coupled” to another element, it should be understood that no intervening elements are present in the “direct” connection between the elements. However, the existence of a direct connection does not exclude other connections, in which intervening elements may be present. When an element is referred to herein as being “electrically coupled” to another element, it is to be understood that the element can directly connected by an electrical conductor to another element.

When an element is referred to herein as being “disposed” in some manner relative to another element (e.g., disposed on, disposed between, disposed under, disposed adjacent to, or disposed in some other relative manner), it is to be understood that the elements can be directly disposed relative to the other element (e.g., disposed directly on another element), or have intervening elements present between the elements. In contrast, when an element is referred to as being “disposed directly” relative to another element, it should be understood that no intervening elements are present in the “direct” example. However, the existence of a direct disposition does not exclude other examples in which intervening elements may be present.

Similarly, when an element is referred to herein as being “bonded” to another element, it is to be understood that the elements can be directly bonded to the other element (without any intervening elements) or have intervening elements present between the bonded elements. In contrast, when an element is referred to as being “directly bonded” to another element, it should be understood that no intervening elements are present in the “direct” bond between the elements. However, the existence of direct bonding does not exclude other forms of bonding, in which intervening elements may be present.

Likewise, when an element is referred to herein as being a “layer,” it is to be understood that the layer can be a single layer or include multiple layers. For example, a conductive layer may comprise multiple different conductive materials or multiple layers of different conductive materials, and a dielectric layer may comprise multiple dielectric materials or multiple layers of dielectric materials. When a layer is described as being coupled or connected to another layer, it is to be understood that the coupled or connected layers may include intervening elements present between the coupled or connected layers. In contrast, when a layer is referred to as being “directly” connected or coupled to another layer, it should be understood that no intervening elements are present between the layers. However, the existence of directly coupled or connected layers does not exclude other connections in which intervening elements may be present.

Moreover, the terms left, right, front, back, top, bottom, forward, reverse, clockwise and counterclockwise are used for purposes of explanation only and are not limited to any fixed direction or orientation. Rather, they are used merely to indicate relative locations and/or directions between various parts of an object and/or components.

Furthermore, the methods and processes described herein may be described in a particular order for ease of description. However, it should be understood that, unless the context dictates otherwise, intervening processes may take place before and/or after any portion of the described process, and further various procedures may be reordered, added, and/or omitted in accordance with various embodiments.

Unless otherwise indicated, all numbers used herein to express quantities, dimensions, and so forth should be understood as being modified in all instances by the term “about.” In this application, the use of the singular includes the plural unless specifically stated otherwise, and use of the terms “and” and “or” means “and/or” unless otherwise indicated. Moreover, the use of the terms “including” and “having,” as well as other forms, such as “includes,” “included,” “has,” “have,” and “had,” should be considered non-exclusive. Also, terms such as “element” or “component” encompass both elements and components comprising one unit and elements and components that comprise more than one unit, unless specifically stated otherwise.

As used herein, the phrase “at least one of” preceding a series of items, with the term “and” or “or” to separate any of the items, modifies the list as a whole, rather than each member of the list (i.e., each item). The phrase “at least one of” does not require selection of at least one of each item listed; rather, the phrase allows a meaning that includes at least one of any one of the items, and/or at least one of any combination of the items. By way of example, the phrases “at least one of A, B, and C” or “at least one of A, B, or C” each refer to only A, only B, or only C; and/or any combination of A, B, and C. In instances where it is intended that a selection be of “at least one of each of A, B, and C,” or alternatively, “at least one of A, at least one of B, and at least one of C,” it is expressly described as such.

While some features and aspects have been described with respect to the embodiments, one skilled in the art will recognize that numerous modifications are possible. For example, the methods and processes described herein may be implemented using hardware components, custom integrated circuits (ICs), programmable logic, and/or any combination thereof. Further, while various methods and processes described herein may be described with respect to particular structural and/or functional components for ease of description, methods provided by various embodiments are not limited to any particular structural and/or functional architecture but instead can be implemented in any suitable hardware configuration. Similarly, while some functionality is ascribed to one or more system components, unless the context dictates otherwise, this functionality can be distributed among various other system components in accordance with the several embodiments.

Moreover, while the procedures of the methods and processes described herein are described in a particular order for ease of description, unless the context dictates otherwise, various procedures may be reordered, added, and/or omitted in accordance with various embodiments. Moreover, the procedures described with respect to one method or process may be incorporated within other described methods or processes; likewise, system components described according to a particular structural architecture and/or with respect to one system may be organized in alternative structural architectures and/or incorporated within other described systems. Hence, while various embodiments are described with or without some features for ease of description and to illustrate aspects of those embodiments, the various components and/or features described herein with respect to a particular embodiment can be substituted, added and/or subtracted from among other described embodiments, unless the context dictates otherwise. Consequently, although several embodiments are described above, it will be appreciated that the invention is intended to cover all modifications and equivalents within the scope of the following claims.

In an exemplary embodiment, the present disclosure provides a semiconductor device. The semiconductor device also includes a first circuit board may include a first top surface and a first bottom surface separated by a first thickness, the first top surface being characterized by a first area. The device also includes a first circuit coupled to the first top surface of the first circuit board, the first circuit being characterized by a first height from the first top surface. The device also includes a second circuit board comprising a second top surface and a second bottom surface separated by a second thickness, the second bottom surface being characterized by a second area and positioned at a second height opposing to the first top surface, the second top surface being farther from the first top surface than the second bottom surface, the second area being smaller than the first area, the second thickness being no greater than first thickness, the second circuit board comprising a first conductor electrically coupled to the first circuit board. The device also includes a second circuit comprising a third top surface and a third bottom surface separated by a third thickness, the third bottom surface being coupled to the first top surface in the first area of the first circuit board, the third top surface being opposite to the third bottom surface and coupled to the second bottom surface in the second area of the second circuit board. The device also includes a first filling material may include a third height from the first top surface to overlay the first circuit and the second circuit board with a spacing above the second top surface. The device may also include a second filling material enclosing the first conductor and the second circuit. As an example, the term “height” refers to vertical distance, wherein as “thickness” refers to a measurement of the material or component between the two parallel surfaces; height refers to a position, whereas thickness refers to the size or dimension of an object or component, and these terms should not limit the scope of the claims. For example, the term “opposing” to refers relative positioning of two surfaces in a spatial arrangement, where one surface directly faces another surface (rather than being parallel or at an angle to it), and it should not limit the scope of the claims.

Implementations may include one or more of the following features. The semiconductor device may include: a third circuit board comprising a fourth top surface and a fourth bottom surface separated by a fourth thickness, the fourth bottom surface being characterized by a third area and positioned at a fourth height with respect to the first top surface, the fourth top surface being farther from the first top surface than the fourth bottom surface, the third area plus the second area being smaller than the first area, the fourth thickness being no greater than first thickness, the third circuit board comprising a second conductor electrically coupled to the first circuit board; a third circuit comprising a fifth top surface and a fifth bottom surface separated by a fifth thickness, the fifth bottom surface being coupled to the first top surface in the first area of the first circuit board, the fifth top surface being opposite to the fifth bottom surface and coupled to the fourth bottom surface in the third area of the third circuit board; and a third filling material enclosing the second conductor and the third circuit. The third circuit board may include signal paths and routings that at least connect various electrical components of the third circuit to a common ground within the third area in the fourth thickness. The third circuit board and the second circuit board are two portions of one bigger circuit board characterized by a fourth area and the second thickness. The one bigger circuit board may include signal paths and routings that at least connect various electrical components of both the second circuit and the third circuit to a common ground within the fourth area in the second thickness. The second circuit board may include 4 layers with a total thickness being the second thickness of 100 um or less, the 4 layers may include signal paths and routings that at least connect various electrical components of the second circuit to the first circuit board or to a common ground. The first circuit board may include 9 layers with a total thickness being the first thickness of 270 um or less. The second circuit board may include a carrier attached to the second top surface, the carrier may have a thickness of 30 um or after grinding to be leveled with the third height of the first filling material. The semiconductor device may include: a fourth circuit packaged as a single-sided flip-chip die coupled to the first top surface of the first circuit board; a fifth circuit packaged as a single-sided flip-chip die coupled to the first bottom surface of the first circuit board; a fourth filling material may include a fifth height of 70 um or less from the first bottom surface to a third bottom surface to embed the fifth circuit; multiple conducting contacts configured as input/output ports with a height of 5 um on the third bottom surface; and multiple conductor wires coupled to the first top surface of the first circuit board passing through the first filling material, used for compartment shielding. The first circuit may include a surface mount technology device with the first height up to 295 um. The second circuit may include a double-sided fanout die with the third thickness of 140 um or less. The second circuit may include a pre-stacked chip characterized by a total thickness no greater than the third thickness. The second circuit may include a conductor post having a height of 25 um formed on the third bottom surface, the conductor post being configured to couple to a solder joint having a height of 15 um formed either on the first top surface in the first area of the first circuit board or on top of the conductor post. The second circuit may include a conductor pad having a thickness of 5 um formed on the third top surface, the conductor pad being configured to couple to a solder joint having a height of 15 um formed either on the second front surface in the second area of the second circuit board or on top of the conductor pad. The first conductor may include a length equal to the second height or less, may include one or more types selected from vertical wires, tall conductor posts, vias filled with a conducting material, and solder joints with or without high liquidus metal core. Implementations of the described techniques may include hardware, a method or process, or computer software on a computer-accessible medium. In semiconductor packaging, a conductor post refers to a vertical metal structure that is used to connect a semiconductor device to external circuitry. The conductor post may comprise a conductive material, such as copper or gold, and is coupled to the bonding pad on the semiconductor device using a process such as wire bonding or flip-chip bonding.

According to another embodiment, the present disclosure provides a semiconductor device. The semiconductor device also includes a first circuit board may include a first top surface and a first bottom surface separated by a first thickness, the first top surface being characterized by a first area. The device also includes a first circuit coupled to the first top surface of the first circuit board, the first circuit being characterized by a first height from the first top surface. The device also includes a second circuit board may include a second top surface and a second bottom surface separated by a second thickness, the second bottom surface being characterized by a second area and positioned at a second height opposing to the first top surface, the second area being smaller than the first area, the second height plus the second thickness being about the same as the first height. The device also includes a second circuit comprising a third top surface and a third bottom surface separated by a third thickness, the third bottom surface being coupled to the first top surface in the first area of the first circuit board and the third top surface being coupled to the second bottom surface in the second area of the second circuit board. The device also includes a third circuit comprising a fourth top surface and a fourth bottom surface separated by a fourth thickness, the fourth bottom surface being coupled to the first top surface in the first area of the first circuit board and the fourth top surface being coupled to the second bottom surface in the second area of the second circuit board. The device also includes a first mold that may include a third height from the first top surface to enclose the first circuit and the second circuit board with a spacing above the second top surface. The device also includes a second mold that may include the second height from the second bottom surface to enclose the second circuit and the third circuit. The device also includes a through-mold via filled by a conductive material configured to pass through the second mold to electrically couple the second circuit board to the first circuit board.

Implementations may include one or more of the following features. The semiconductor device where the second circuit board may include signal paths and routings that at least connect various electrical components of both the second circuit and the third circuit to a common ground within the second area in the second thickness to allow the first circuit board to be reduced by a size of at least a part of the second area. The third thickness and the fourth thickness may include different values under a condition that a sum of the third thickness plus heights of some coupling structures for coupling the second circuit to the first circuit board and the second circuit board, or a sum of the fourth thickness plus heights of some coupling structures for coupling the third circuit to the first circuit board and the second circuit board, remains to be the second height. Implementations of the described techniques may include hardware, a method or process, or computer software on a computer-accessible medium.

According to yet another embodiment, the present disclosure provides a semiconductor device. The semiconductor device also includes a first circuit board may include a first top surface and a first bottom surface separated by a first thickness, the first top surface being characterized by a first area. The device also includes a first circuit comprising a surface-mount interface coupled to the first top surface in a third portion of the first area of the first circuit board, the first circuit being characterized by a first height from the first top surface. The device also includes a second circuit comprising a first chip coupled to a second circuit board, the first chip comprising a second top surface and a second bottom surface characterized by a second thickness, the second circuit board comprising a third top surface and a third bottom surface separated by a third thickness, the second top surface being attached with a carrier, the third bottom surface being characterized by a second area and being positioned at a second height from the first top surface, the second top surface comprising a first plurality of conductor pads coupled to the third bottom surface in the second area of the second circuit board, the second circuit being coupled to the first circuit board by having a first plurality of conductor posts on the third bottom surface to couple with the first top surface in a first portion of the first area of the first circuit board. The device also includes a second filling material enclosing the first chip on the second circuit board entirely except first recessed regions to expose the first plurality of conductor posts. The device also includes a third circuit comprising a second chip coupled to a third circuit board, the second chip comprising a fourth top surface and a fourth bottom surface characterized by a fourth thickness, the third circuit board comprising a fifth top surface and a fifth bottom surface separated by a fifth thickness, the fifth bottom surface being characterized by a third area and being positioned at a third height from the first top surface, the fourth top surface comprising a second plurality of conductor pads coupled to the fifth bottom surface in the third area of the third circuit board, the third circuit being coupled to the first circuit board by having a second plurality of conductor posts on the fourth bottom surface to couple with the first top surface in a second portion of the first area of the first circuit board. The device also includes a third filling material enclosing the second chip on the third circuit board except second recessed regions to expose the second plurality of conductor posts. The device also includes a first filling material enclosing the first circuit and the third circuit while leveling with a top surface of the carrier attached to the third top surface of the second circuit block, the first filling material filling the first recessed regions and the second recessed regions.

Implementations may include one or more of the following features. The semiconductor device may include: where the first circuit board may include 9 layers or less characterized by a total thickness of 270 um or less; where the second circuit board may include 4 layers characterized by a total thickness of 100 um or less; where the first filling material may include a fourth height over the fifth top surface of the third circuit by a spacing of 50 um or less; where the carrier may include a minimum thickness of 30 um after final grinding of the first filling material; where each of the first and second plurality of conductor posts may include a length of 25 um; where each of the first and second plurality of conductor pads may include a height of 5 um; where each of the third thickness and the fourth thickness may include a value of 140 um or less; and where the first height may include a value up to 295 um.

Using multiple layers to form signal paths and routings in a circuit board refers to the process of creating complex electronic circuits by stacking multiple layers of conductive material on top of each other. This technique, known as multilayer PCB design, allows for the creation of circuits that are more compact, have higher component densities, and can support a greater number of signal paths.

In a multilayer PCB design, layers may be created by laminating a thin sheet of insulating material, typically fiberglass or epoxy, with a layer of copper foil on each side. These layers are then stacked on top of each other, with each layer containing a pattern of conductive traces and pads that connect to components mounted on the board.

By using multiple layers, it is possible to create more complex and dense circuits, as well as provide additional shielding and ground planes to reduce interference and noise. The routing of signals between different layers is accomplished through vias, which are small holes drilled through the layers and coated with conductive material.

The number of layers used in a multilayer PCB design can vary depending on the complexity of the circuit and the desired performance characteristics. Designs can range from two-layer boards for simple circuits, to over 30 layers for high-performance applications such as servers and high-speed communication equipment.

It is to be appreciated that embodiments of the present invention provide many advantages over conventional techniques. In various embodiments, a semiconductor device can be packaged in a compact module without sacrificing functionality. This can be achieved by stacking double-sided dies with sub-sized circuit boards, which reduces the device size without increasing its height. This approach can also reduce the number of layers in the main circuit board, potentially leading to a reduction in overall height. In certain configurations, the sub-sized circuit boards allow for routings and grounding connections to be positioned closer to the double-sided dies, thereby reducing impedance and enhancing electrical performance. The addition of the stacked sub-sized circuit boards also increases the total area, improving module performance while still achieving a smaller module size. For instance, radio-frequency components in the surface-mount device can maintain their original size and height, preserving high RF performance with a high Q value within a smaller module size. Additionally, all chip dies and SMT components can maintain their original spacing in the x and y directions, minimizing crosstalk and improving RF performance.

Embodiments of the present invention can be implemented in conjunction with existing systems and processes. For example, context information sharing among applications according to embodiments of the present invention may be implemented according to various operating systems. Additionally, various techniques according to the present invention can be adopted into existing systems via software installation and updates. There are other benefits as well.

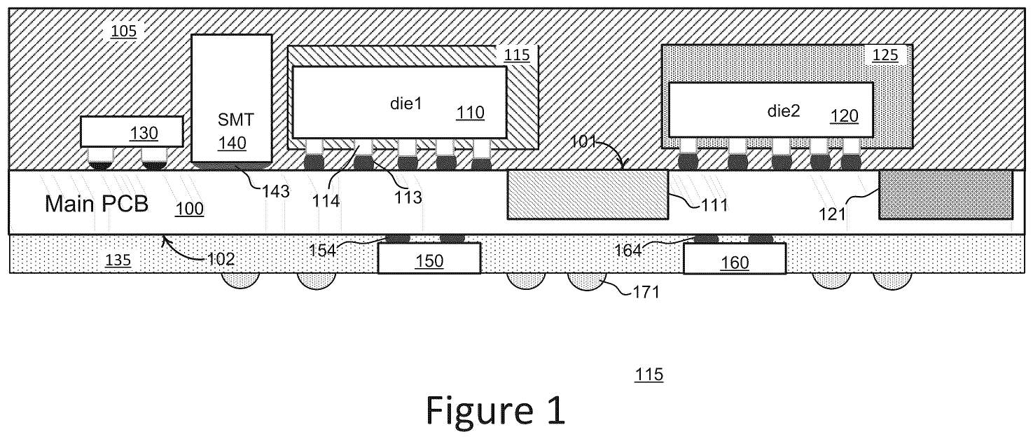

In one approach for packaging a conventional double-sided module, all components made by surface mount technology (SMT) and circuits in a form of flip-chip (FC) dies are mounted on a surface of a printed circuit board (PCB), e.g., a main PCB. Routings and grounding planes are built inside multiple layers within the PCB. According to certain embodiments, SMT devices are electronic components that are designed to be mounted directly onto the surface of a printed circuit board (PCB), without the use of leads or wires. These components are typically smaller and more compact than their through-hole counterparts, and offer several advantages in terms of performance, cost, and ease of assembly. However, a SMT device is not limited to this description and can include other types of chips. This approach is shown in FIG. 1 as a simplified illustration. This diagram is merely an example, which should not unduly limit the scope of the claims. One of ordinary skill in the art would recognize many variations, alternatives, and modifications. As shown, a double-sided module is based on a main PCB 100. The main PCB 100 includes a top surface 101 and a bottom surface 102, both surfaces being configured to couple several semiconductor components. An SMT device 140 is attached to the top surface (101) using a surface-mount interface structure 143. This device, for instance, may be a radio frequency (RF) capacitor, inductor or filter with a specified high Q value, depending on the application. The SMT device 140 is the tallest component on the top surface (101), which can limit the ability to reduce the module height without affecting its functionality. As depicted in FIG. 1, several circuits in the form of chip dies are also connected to the top surface 101. For example, a first circuit 110 in the form of a flip-chip die (die 1) is joined to the top surface (101) via a conductor (copper) post 114 that is connected to a conductor joint 113. A flip-chip die, or simply a die, refers to a small piece of semiconductor material, typically made of silicon, on which a microelectronic circuit is constructed. It is the basic unit of integrated circuits and forms the basis for various electronic devices, such as microprocessors, memory chips, and ASICs. In certain embodiments, the first circuit 110 is enclosed within a filling material 115.

Second circuit 120 comprises a flip-chip die (die 2) that is coupled via a conductor (copper) post coupling with a conductor (solder) joint on the top surface (101). The second circuit 110 is encapsulated in a filling material 125. Depending on the applications, an additional number of circuits similar to first circuit 110 or second circuit 120 may be also coupled with the top surface (101).

For the circuits added to the top surface (101), the main PCB 100 needs to allocate a certain area for building relevant metal routings and grounding the common plane into multiple PCB layers therein. For example, the main PCB includes 9 layers with a total thickness of 270 um. For first circuit 110, first region 111 in the main PCB 100 is mainly used for building metal routings, grounding connections or matching network for the first circuit 110. For the second circuit 120, second region 112 in main PCB 100 could be mainly utilized to construct metal routings, grounding connections and matching component to the first circuit 120. Additionally, single-sided flip-chip circuits 130 may be incorporated to link with the top surface 101 using copper-pillars as electrical connections. Metal routings and groundings are built in PCB 100 layers for communications among the first circuits 110 and 120, circuits 130, SMT device 140 and I/O 171. In general, the size and layer count reduction of the overall PCB is limited by the amount of space required for metal routing and grounding connections to all circuits located on the top surface (101).

On the bottom surface 102 of the main PCB 100, usually only flip-chip (FC) dies, e.g., 150 and 160, are mounted via copper pillars or solder bumps 154 and 164. A thickness of another molding material 135 is used to encapsulate flip-chip dies 150 and 160. The final thickness of 135 may be limited to no more than 70 um after molding and grinding. Some metal balls or metal pads 171 may be formed at the bottom surface of the filling material 130, serving as I/O to motherboard. For example, the metal bump 171 is made by Ni/Cu with a height of 5 um. According to certain embodiments, a conductor pad refers to a small area of conductive material on a semiconductor device that is used in semiconductor packaging to make an electrical connection between the device and external circuitry. The conductor pad is typically made of a metal such as copper, gold, or aluminum, and is designed to be bonded to a conductor post or wire using a process such as wire bonding or flip-chip bonding. However, a conductor pad is not limited to this description and can include other types of conductive bonding for semiconductor packaging.

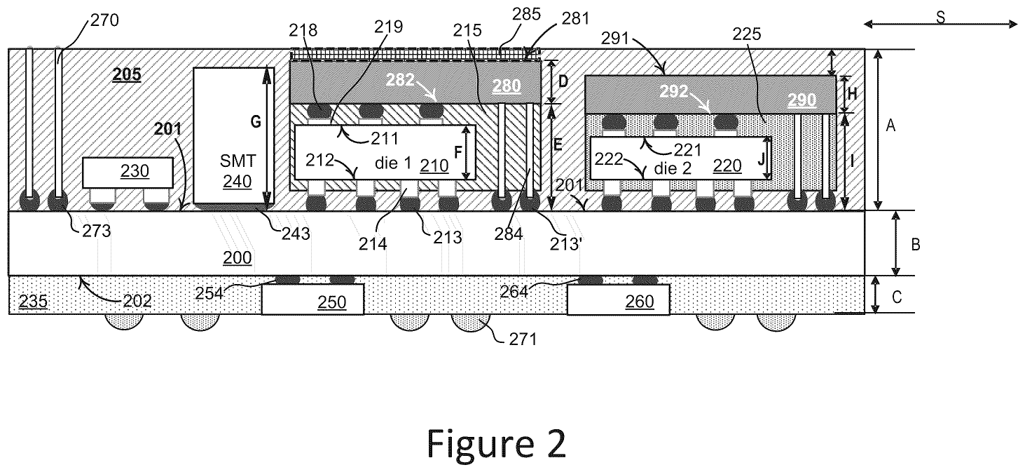

FIG. 2 is a simplified diagram to illustrate a double-sided semiconductor module according to embodiments of the present invention. This diagram is merely an example, which should not unduly limit the scope of the claims. One of ordinary skill in the art would recognize many variations, alternatives, and modifications. As shown, a double-sided semiconductor module is packaged based on a first circuit board 200 on both a top surface 201 and a bottom surface 202. The first circuit board 200 may be a multi-layered printed circuit board with a total thickness B and allowable for double-sided mounting of various semiconductor integrated circuits (IC) components. For example, first circuit board 200 comprises a 9-layer PCB having a total thickness of B=270 um or less, designed with mounting flexibility and increasing the packaging density of IC components. In another example, thickness B of the first circuit board may be 250 um. A layer refers to a flat conductive material in the PCB that is sandwiched between insulating layers and serves as a pathway for electrical signals. To minimize the size or height of a double-sided semiconductor module, it is crucial to carefully consider various factors such as layer counts, trace routing/grounding arrangement, via placement, and thermal management. This will ensure that the electronic components on the smaller circuit board operate reliably and efficiently. Moreover, it is equally important to take into account electromagnetic compatibility (EMC) and electromagnetic interference (EMI), which can negatively impact the performance and functionality of both the board and the components on the board.

According to certain embodiments, a double-sided fanout chip is a type of semiconductor package that is designed to provide increased functionality and reduced size for electronic devices. The package comprises a thin silicon chip that is mounted onto a substrate, with conductive traces and vias connecting the chip to pads on the top and bottom surfaces of the substrate. The fanout design of the package allows for the routing of signals from the chip to a greater number of pads, which can then be connected to external circuitry. This increased functionality is particularly useful in applications where space is at a premium, such as mobile devices and wearables. The double-sided design of the package allows for the placement of components on both the top and bottom surfaces of the substrate, increasing the density of the circuit and reducing the overall size of the package. This design also allows for more efficient heat dissipation, as heat can be transferred away from the chip through both the top and bottom surfaces of the package. However, a double-sided fanout chip is not limited to this description and can include other types of chips.

Multiple semiconductor components are placed on the top surface 201, which serves as the first area for mounting various components. Among the components, the first circuit 240 is the leading height-limiting factor, with a height “G” measured from the top surface 201 of the first circuit board 200, where it is mounted solder joint 243. For example, in the case of high-power RF components, the height “G” can reach up to 295 um to maintain optimal performance and a high Q value. To minimize the module size without increasing height or sacrificing functionality, other components with lower heights are rearranged in certain embodiments.

In an embodiment, as shown in FIG. 2, a first circuit block, including a second circuit 210 with its top surface 211 coupled to a bottom surface 282 of a second circuit board 280, is mounted on the first circuit board 200 by having a bottom surface 212 of the second circuit 210 coupled to top surface 201. For example, second circuit 210 is provided as a double-sided fanout die. In the embodiment, top surface 211 of second circuit 210 includes a plurality of conductor pads 219. Conductor pads 219 are made by wafer metallization and can use copper as the pad material for achieving high electrical conductivity. Bottom surface 212 of second circuit 210 includes a plurality of conductor posts 214. Conductor post 214 can be made through Cu-plating on circuit wafer and grinding after molding to obtain a certain height required for the application. The second circuit board 280 may be configured to mount semiconductor components on just one surface, e.g., its bottom surface 282. For example, second circuit board 280 comprises a 4-layer PCB with a total height of D=100 um or less.

In an embodiment, the second circuit board 280 may include a carrier 285 attached to its top surface 281, or it may not have a carrier. According to certain embodiments, a carrier refers to a temporary substrate that is used to hold and transport semiconductor devices during the manufacturing process of semiconductor packaging. The carrier is typically made of a non-conductive material, such as ceramic or plastic, and is designed to securely hold the devices in place while they are being processed. However, a carrier is not limited to this description and can include other types of substrates or wafers. The carrier is utilized during the manufacturing process of the second circuit board and can be constructed from a variety of materials such as plastic, metal, or ceramics. The choice of material depends on an implementation's specific requirements, including durability, heat resistance, and compatibility with the manufacturing equipment. For example, the carrier may need to support multiple PCBs. To reduce the size of the module, the carrier height is approximately 30 um or more limited by height A after final grinding of filling material 205, ensuring that the top surface of the carrier is leveled with the top surface of the filling material.

In an embodiment, second circuit board 280 features a plurality of conductor joints on its bottom surface 282, which can be solder joints with a height of 15 um, or other suitable conductor materials and types of conductor joints. The second circuit 210 is then attached to the second circuit board 280 by aligning the plurality of conductor pads 219 on its top surface 211 to the bottom surface 282. The plurality of conductor joints 218 could either be built on top of the plurality of conductor pads 219, or on the bottom surface 282. The second circuit 210 is then encapsulated in a filling material 215, which serves as a dielectric layer and protects the components on the board. The filling material may include an epoxy mold compound (EMC) that is applied surrounding the components and cured to form a solid protective layer. The height of the filling material extends from the bottom surface 282 to the plurality of conductor posts 214, ensuring complete coverage and protection for the second circuit 210 and its connections to the second circuit board 280.

In this embodiment, as depicted in FIG. 2, the first circuit block is connected to the first circuit board 200 using the plurality of conductor (copper) posts 214 located on the bottom surface 212 of the second circuit 210. A plurality of conductor joints 213 can either be formed on the top surface 201 of the first circuit board 200, or on top of the plurality of conductor (copper) posts 214. Conductor joints 213, like the conductor joints 218 on the bottom surface 282 of the second circuit board 280, have a height of approximately 15 um and may be made from the same or different conductive materials. The height of the conductor posts 214 may vary to accommodate the height F of the second circuit 210. In various implementations, with the second circuit board 280 stacked on top of the second circuit 210, the total height of the first circuit block is the sum of the height of the second circuit board 280, the height of conductor joint 218, the height of conductor pad 219, the height of the second circuit 210, the height of conductor post 214, and the height of conductor joint 213. To ensure that the module height is not increased, the total height of the first circuit block is kept comparable to the height G of the first circuit 240. With this arrangement, the bottom surface 282 of the second circuit board 280 is positioned opposite the top surface 201 of the first circuit board 200 at a height E measured from the top surface 201 of the first circuit board 200.

In an embodiment, the second circuit board 280 is provided as a smaller sub-sized board in comparison to the main circuit board 200. Despite its smaller size, the second area of circuit board 280 provides ample space to accommodate all the necessary metal routing and grounding connections required for the components within the second circuit 210. Circuit board 280 includes multiple conductor wires 284, each having a vertical length E, which extend through the filling material 215 and connect through the solder joints 213 located on the top surface 201 of the main circuit board 200 to the main circuit board 200. This arrangement allows for the elimination of a portion of the first area that was previously utilized for holding the metal routing and grounding traces for the second circuit 210. As a result, this helps to save valuable space and reduce the overall size of the module.

In an embodiment, the double-sided semiconductor module is designed with a compact layout, as demonstrated in FIG. 2. The module includes a second circuit block, which is mounted on top surface 201 of the first circuit board 200. The second circuit block comprises a third circuit 220, which is attached to the bottom surface 292 of a third circuit board 290. The third circuit 220 may be provided as a double-sided fanout die with a thickness J and its bottom surface is connected to the top surface 201 of the first circuit board 200. The third circuit board 290 has a thickness H of around 100 um and serves as a 4-layer PCB, providing space for the routing and grounding traces of the third circuit 220, as well as multiple conductor wires. Similar to second circuit board 280, third circuit board 290 is smaller than the main circuit board 200, making it another sub-sized circuit board. The thickness J of third circuit 220 could be the same or may be different from the thickness F of the second circuit 210, making it possible to have a more flexible design for the double-sided semiconductor module. By stacking the third circuit board 290 on top of third circuit 220, a second portion of the first area originally used for routing/grounding traces of the third circuit 220 can be saved, leading to a reduction in the first area of the main circuit board 200. The reduction in the first area, indicated by lateral dimension S in FIG. 2, results in a smaller module size without increasing the height and compromising the functionality of the module.

In an embodiment, referring to FIG. 2, the double-sided semiconductor module features a filling material 205 that encapsulates components mounted on the top surface 201 of the first circuit board 200. This filling material 205, which may include an epoxy mold compound, is molded to conform to the complex shapes around the various components and electrical coupling joints on the PCB. Filling material 205 provides robust protection against physical and environmental hazards, including moisture, dust, and mechanical stress. It is applied to a height A that is level with the top surface of carrier 285 attached to the second circuit board 280. Height A may exceed the height G of the tallest component, such as the SMT device, and provide a clearance of approximately 40 um over the top surface of SMT component 240.

As described in FIG. 2, the double-sided semiconductor module may be equipped with additional conductor wires 270 for enhanced protection against electromagnetic interference (EMI) between the compactly packaged semiconductor components on the top surface 201 of the PCB. Conductor wires 270 are vertically coupled to respective solder joints 273 on top surface 201, serving as a shield against EMI. This provides a more efficient and effective solution to reduce the electromagnetic interference between the various components on the same PCB, ensuring stable and reliable operation.

The double-sided semiconductor module includes two additional circuits, fourth circuit 250 and fifth circuit 260. Both circuits are electrically coupled to the bottom surface 202 of the first circuit board 200 through flip-chip connections 254 and 264, respectively. A protective EMC material 235 is applied on top of the bottom surface 202 and encompasses both fourth circuit 250 and fifth circuit 260. The thickness of the EMC material 235 is C, as an example, may be 70 um or less to allow both circuits to be embedded within the material with only their bottom surface exposed after bottom mold grinding. To provide input/output functionality to the double-sided semiconductor module, multiple conducting contacts 271 may be formed at the bottom surface of the EMC material 235. These contacts can be made of Ni/Cu alloy pads with a thickness of 5 um, for example, and serve as the input/output ports for the module. This compact design allows for a large number of functions to be integrated into the same device while maintaining a low profile and ensuring protection against physical and environmental hazards.

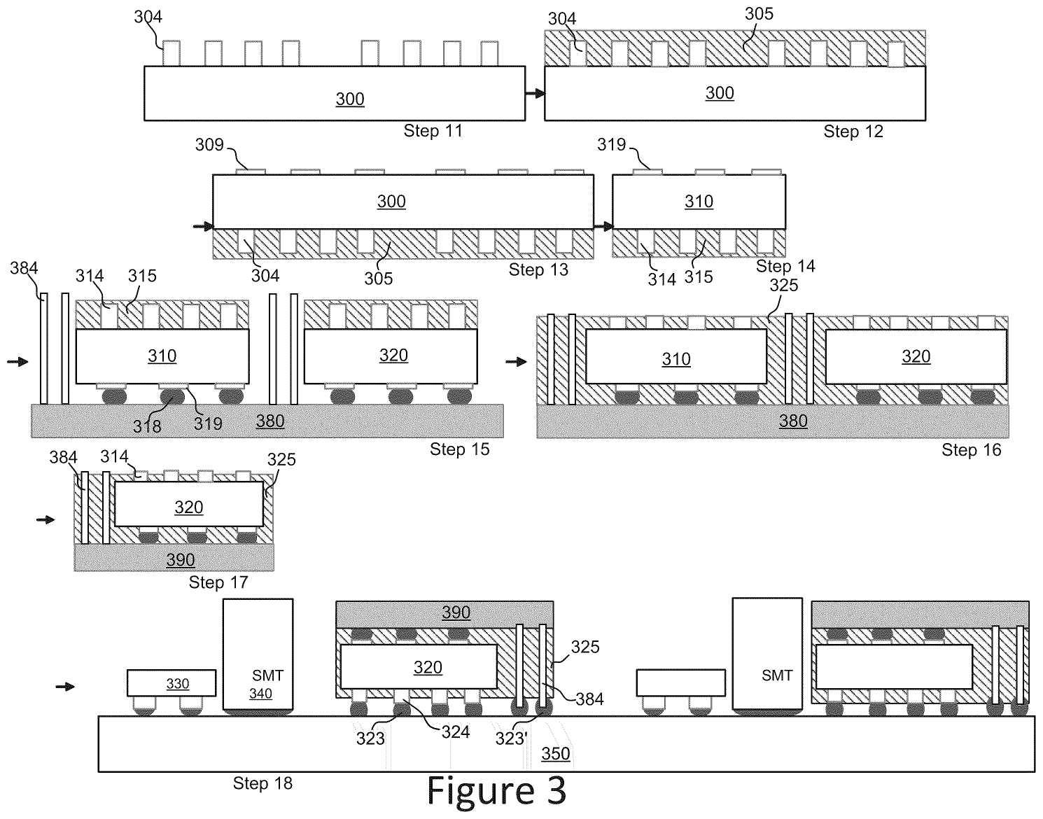

FIG. 3 a simplified diagram to illustrate a process flow of forming a double-sided fanout chip package according to an embodiment of the present invention. This diagram is merely an example, which should not unduly limit the scope of the claims. One of ordinary skill in the art would recognize many variations, alternatives, and modifications. A semiconductor wafer 300 is provided as the starting point for forming a double-sided fanout chip package. The wafer includes two surfaces: a first surface and a second surface opposite to the first. In an embodiment, the wafer 300 comprises multiple prefabricated semiconductor circuits, each similar to second circuit 210 or third circuit 220 in FIG. 2. The process at step 11 involves forming multiple conductor posts 304 on the first surface of the wafer 300, as shown in FIG. 3. For instance, the conductor posts 304 can be copper posts created using a copper electroplating process with a height of 60 um. The height of the conductor posts 304 can be optionally adjusted depending on the application. For example, copper posts could be 25 um in height after mold grinding in step 12. The electroplating process, which utilizes an electric current to deposit metal from a solution onto the substrate, allows for precise control of the copper post thickness by adjusting the current and duration of the plating process. The multiple copper posts 304 may be grouped such that each group corresponds to one circuit within the wafer 300.

The process continues at step 12, where a filling material 305 is applied to encase the multiple conductor posts 304 formed on the first surface of the wafer 300. The filling material 305 may include an epoxy mold compound with a thickness exceeding the height of the conductor posts 304. The EMC material is then cured to secure the conductor posts 304 in place. Subsequently, a grinding process is performed to reduce the thickness of the EMC material until the conductor posts 304 are nearly exposed (although it is not necessary to fully expose them at this stage). The conductor post 304 can remain as its initial thickness of 60 um if not exposed after mold grinding or become shorter if exposed after mold grinding.

The process continues at step 13 with the flipping of the wafer 300 and the formation of multiple conductor pads 309 on the second surface of the wafer 300. The conductor pads 309 may be copper pads created through a metallization process that includes wafer cleaning, patterning, seed layer deposition, copper deposition, and annealing of the metallization. Copper pads can be produced with varying thicknesses, typically 5 um or less. Copper deposition may be performed through an electroplating process, where an electric current is utilized to deposit the metal from a solution onto the substrate. The thickness of the copper pads may be precisely controlled by adjusting the current and duration of the plating process. The multiple conductor pads 309 may be also grouped according to the locations of their respective circuits within the wafer.

At step 14, the process involves wafer singulation, in which the wafer 300 undergoes a series of cuts to separate individual circuit block, which contains features (conductor posts and pads on both surfaces), from the wafer 300. As depicted, an individual circuit block is obtained, which includes a circuit 310, a group of conductor posts 314 on the first surface of the circuit 310, an encasing and securing mold 315 for the group of conductor posts 314, and a group of conductor pads 319 on the second surface of the circuit 310.

The process further continues by providing a circuit board 380. Circuit board 380 has a top surface and a bottom surface. Additionally, circuit board 380 also includes multiple mounting sites including a group of conductor (solder) joints 318 formed on the top surface, each mounting site being prepared according to a design for mounting an individual circuit block obtained by wafer singulation. The conducting solder joints 318 may alternatively be formed on the top surface of conductor pads 319 at wafer level. Prior to assembly, the solder could either be formed on the submodule bottom side as solder bumps (more than 15 um) or on the main circuit board top side by solder paste printing (sort of liquid, no defined height). The solder joints can be limited to 15 um height after assembling to the circuit board followed by reflow. Circuit board 380 itself has a portion with several layers for each mounting site where some metal routing traces and grounding connection paths are prebuilt for the to-be-mounted circuit block. At step 15, the process includes assembling multiple, e.g., two, circuit blocks to the circuit board 380. One circuit block containing circuit 310 is mounted to one mounting site by coupling the group of conductor pads 319 through corresponding group of conductor joints 318 to the top surface of the circuit board 380. Another circuit block containing circuit 320 is mounted to another mounting site on the top surface of the circuit board 380. There could be other flip-chip dies and SMT components mounted to the top surface of 380 in step 15. The vertical wires 384 are configured to form electrical connections to the routings/grounding traces in the portion per mounting site on the circuit board.

The process also includes, at step 16, applying a filling material 325 (e.g., EMC material) to enclosing the assembled circuit blocks as well as the vertical wires 384 on the top surface of circuit board 380. The filling material 325 will be cured and a grinding process will be performed to thin the mold to expose tips of the vertical wires 384 as well as the conductor posts associated with respective circuits (310 and 320) in the enclosed circuit blocks. An EMC recess process could be applied after EMC grinding process to further expose tips of the vertical wires 384 as well as the conductor posts 314. Overall, on the circuit board 380, array of circuit blocks including associated vertical wires for electrical connections are assembled and molded in the EMC material. When referring to a semiconductor encapsulating process, “enclosing” typically refers to the process of surrounding the semiconductor die with a protective package. The enclosure is typically made of a non-conductive material, such as the mentioned EMC material, and is designed to protect the die from environmental factors, such as moisture, dust, and physical damage.

At step 17, the process for forming the double-sided fanout chip package further include a circuit board singulation by cutting through the array of assembled circuit blocks to obtain each individual assembled circuit blocks. As shown in FIG. 3, one assembled circuit block is obtained, including a circuit 320 with one side electrically coupled to a sub-sized circuit board 390 by a group of conductor pad/joint pairs, another side with a group of conductor posts 314 enclosed in the EMC material 325 with post tips being exposed, and vertical wires 384 enclosed in the EMC material 325 with wire tips being exposed. The vertical wires 384 connect the sub-sized circuit board 390 to the main circuit board 350 in step 18.

At step 18, the process further includes assembling each assembled circuit block onto a main circuit board 350. In an implementation, main circuit board 350 has a top surface and a bottom surface. Main circuit board 350 could have semiconductor components such as single-sided flip-chip die 330 and SMT component 340 with a tall height being mounted on the top surface. Main circuit board 350 further includes some mounting sites, assembling respective one of assembled circuit blocks obtained by circuit board singulation through a group of conductor joints 323 and 323′ formed either on the top surface of the main circuit board 350 or on top of the copper posts 324 associated with circuit 320. Assembling an assembled individual circuit block to the top surface in the step is performed by coupling the exposed tips of conductor posts 324 associated with circuit 320 in the assembled circuit block through the corresponding conductor joints 323 to the top surface of main circuit board 350. The vertical wires 384 also is coupled through corresponding other conductor joints 323′ on the top surface of main circuit board for forming electrical connections between sub-sized circuit board 390 and main circuit board 350. Thus, a double-sided semiconductor module according to embodiments of the present invention is formed with all components on one (top) surface of the main circuit board 350 followed by top side molding (not shown in FIG. 3). The process for packaging other components on another (bottom) surface of the main circuit board 390 can be performed, not shown in FIG. 3, by mounting some single-sided flip-chip dies enclosed by a relatively thin EMC material and adding some I/O ports at a bottom surface of the thin EMC material. Typically, at step 18, multiple units of the double-sided semiconductor modules can be assembled, then individual units of the packaged double-sided semiconductor module can be obtained. One of the main differences between the single-sided fanout chip and the double-sided fanout chip is the number of sides on which the package has conductive traces and vias. As the name suggests, single-sided fanout chips have conductive traces and vias on only one side of the package, while double-sided fanout chips have them on both sides. This means that double-sided fanout chips can accommodate more connections and offer more routing options than single-sided fanout chips.

In an alternative embodiment, at step 15, multiple individual circuit blocks are assembled onto the circuit board 380 which does not include vertical wires 384. Then, at step 16, after applying the filling material 325 to enclose the multiple circuit blocks assembled on the circuit board 380, at least one through-mold via is formed to be associated with each circuit block. Further, at step 17, a via filling process is performed to fill a conductive material in the each through-mold via to form electrical connection to the routings/grounding traces associated with a respective one circuit (310 or 320) built in the circuit board 380. A circuit board singulation process is performed to obtain individual assembled circuit block on a sub-sized circuit board. Lastly, the individual circuit block can be assembled to a main circuit board to form the double-sided semiconductor module with stacked sub-sized circuit board on a double-sided circuit (320).

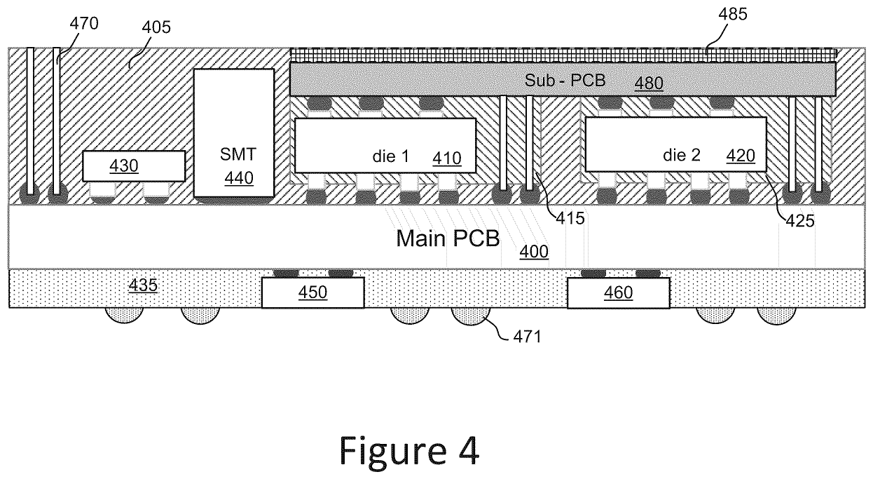

FIG. 4 is a simplified diagram to illustrate a double-sided semiconductor module according to another embodiment of the present invention. This diagram is merely an example, which should not unduly limit the scope of the claims. One of ordinary skill in the art would recognize many variations, alternatives, and modifications. In the embodiment, the double-sided semiconductor module includes one sub-sized circuit board 480 stacked on top of two double-sided dies (410 and 420) coupled with top surface of a main circuit board 400. The sub-sized circuit board 480 is characterized by a second area smaller than a first area of the main circuit board 400. Circuit 410 has its top surface being coupled to a bottom surface of the sub-sized circuit board 480 by a group of conductor pad/joint pairs, and its bottom surface being coupled to a top surface of main circuit board 400 by a group of conductor post/joint pairs. Sub-sized circuit board 480 is electrically coupled to main circuit board 400 by multiple vertical wires 415. Circuit 420 is also coupled between sub-sized circuit board 480 and main circuit board 400 the same way as circuit 410. Compared to the embodiment shown in FIG. 2, a single bigger size sub-sized circuit board replaces two smaller sub-sized circuit boards. This is implemented usually when the two circuits (410 and 420) have the same height. This implementation is not only to simplify the overall packaging process but also may potentially save more area for the main circuit board for the purpose of module size reduction.

In the embodiment, circuit 410 and circuit 420 may be pre-enclosed or molded by an EMC material 415 or 425, which can be provided with a same or different material. The filling material 405 for the final module also may be the same or different from EMC material 415 or 425. The filling material is made with a height sufficient for fully enclosing all semiconductor components, including single-sided flip-chip die 430 and SMT component 440 with a high height, with a clearance over a top surface of the sub-sized circuit board 480. Optionally, a carrier 485 is attached to the top surface of the sub-sized circuit 480. The filling material 405 has a top surface being leveled with a top surface of the carrier 485, leaving a minimum thickness of the carrier to be 30 um. Each of circuit 410 and circuit 420 may be provided in the form of double-sided fanout chip package. The total number of such circuits in this package is not limited to 2.

In the embodiment, the bottom surface of main circuit board 400 are used to mount several flip-chip dies (450 and 460). Another filling material 435 is applied to overlay all components mounted on the bottom surface of the main circuit board 400. The thickness of the filling material 435 is about 70 um after bottom mold grinding, being leveled with bottom surfaces of those flip-chip dies (450 and 460). Some metal balls 471 may be formed on the bottom surface of the filling material 435, configured to be input/output interfaces for the main circuit board. On the top surface of the main circuit board 400, some vertical wires 470 may be formed to provide compartment shielding for the components in the double-sided semiconductor module. When referring to a semiconductor encapsulating process, the term “overlay” typically describes the process of covering the semiconductor die with a protective layer of filling material. The overlay is usually made of a non-conductive filling material, such as a polymer or epoxy resin, and is applied over the die to protect it from environmental factors, such as moisture, dust, and physical damage.

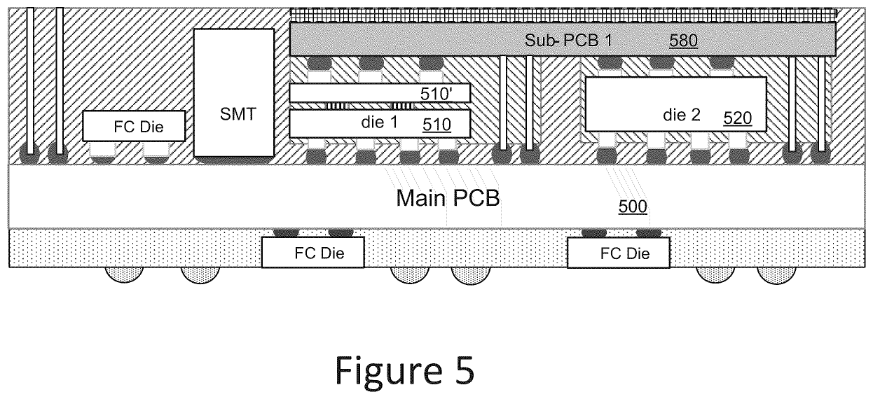

FIG. 5 is a simplified diagram to illustrate a double-sided semiconductor module according to yet another embodiment of the present invention. This diagram is merely an example, which should not unduly limit the scope of the claims. One of ordinary skill in the art would recognize many variations, alternatives, and modifications. In an embodiment, the present disclosure provides a double-sided semiconductor module packaged in a similar manner to the double-sided semiconductor module depicted in FIG. 4. In contrast, each circuit configured with a double-sided chip package may comprise multiple thinner circuits stacked on top of one another. For example, die 1 comprises a circuit, similar to circuit 410, that is a double-sided fanout chip package mounted between two circuit boards. This circuit includes circuit 510 that is pre-stacked on top of it during its own circuit block process. According to certain embodiments, a pre-stacked chip comprises a type of semiconductor package that comprises two or more individual chips that are stacked vertically and interconnected with through-silicon vias (TSVs) or wire bonds. The individual chips can be identical or different, depending on the specific application. Circuit 510 couples to the top surface of the main circuit board 500 via a group of conductor post/joint pairs and is coupled to the bottom side of circuit 510′ through conductor pads or posts. The top side of circuit 510′ is further coupled to the bottom surface of the sub-sized circuit board 580. To maintain the goal of not increasing the height of the double-sided semiconductor module, the total thickness of the stacked circuits 510 and 510′ should be approximately equivalent to the height of a single circuit like circuit 410 in FIG. 4. Circuit 520 comprises a single double-sided fanout chip circuit (e.g., die 2) without stacking, and it is mounted between the same sub-sized circuit board 580 and main circuit board 500. The height of the stacked circuits 510 and 510′ may be similar to the height of circuit 520 to simplify processing. For instance, the height of the stacked circuits 510 and 510′ and the height of circuit 520 may be around 140 um.

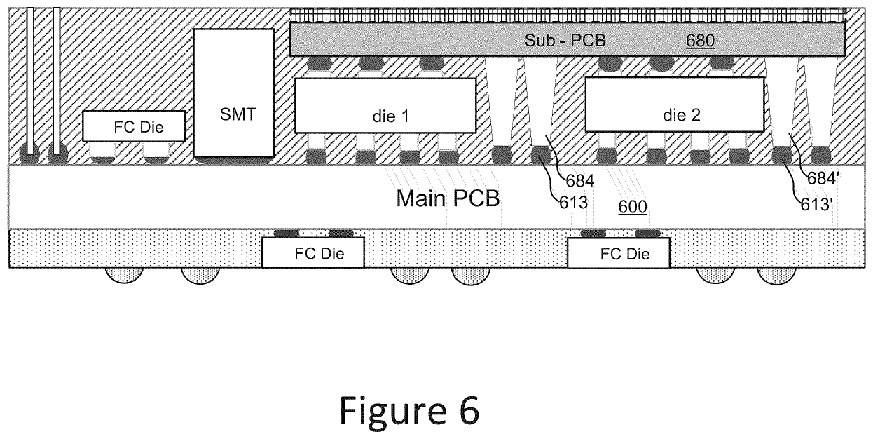

FIG. 6 is a simplified diagram to illustrate a double-sided semiconductor module according to still another embodiment of the present invention. This diagram is merely an example, which should not unduly limit the scope of the claims. One of ordinary skill in the art would recognize many variations, alternatives, and modifications. In the embodiment, the double-sided semiconductor module is packaged substantially the same as the double-sided semiconductor module shown in FIG. 4. Both circuits (e.g., die 1 and die 2) are double-sided fanout chip packages, with their top surfaces coupled to a sub-sized PCB 680 and their bottom surfaces coupled to a main PCB 600. But the connections between sub-sided PCB 680 and main PCB are replaced by conducting through-mold vias (e.g., 684 and 684′). In a specific embodiment, the sub-sized PCB 680 includes a first portion of its board area to contain all metal traces for routings and connections to a common ground for supporting circuit die 1. The conducting through-mold vias 684 are coupled through corresponding conducting joints 613 to the top surface of main PCB 600 for providing electrical connections between the first portion of sub-sized PCB 680 and main PCB 600. A second portion of the sub-sized PCB 680 is used for all metal traces for routings and connections to a common ground for supporting circuit die 2. The conducting through-mold vias 684′ are configured to connect through conducting joints 613′ to the top surface of main PCB 600 to provide electrical connection between the second portion of the sub-sized PCB 680 and main PCB 600.

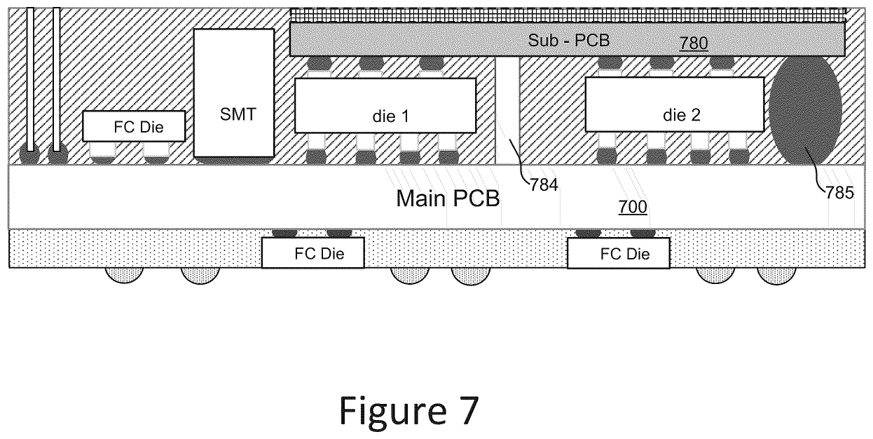

FIG. 7 is a simplified diagram to illustrate a double-sided semiconductor module according to yet still another embodiment of the present invention. This diagram is merely an example, which should not unduly limit the scope of the claims. One of ordinary skill in the art would recognize many variations, alternatives, and modifications. In the embodiment, the double-sided semiconductor module is packaged substantially the same as the double-sided semiconductor module shown in FIG. 4. Both circuits (die 1 and die 2) are double-sided fanout chip packages, with their top surfaces coupled to a sub-sized PCB 780 and their bottom surfaces coupled to a main PCB 700. But the connections between sub-sided PCB 780 and main PCB are replaced by a conducting tall pillar 784 or a tall solder ball 785. In a specific embodiment, the sub-sized PCB 680 includes a first portion of its board area to contain all metal traces for routings and connections to a common ground for supporting circuit die 1. The conducting tall pillar 784 is coupled between the top surface of main PCB 600 and the bottom surface of sub-sized PCB 780 for providing electrical connections between the first portion of sub-sized PCB 780 and main PCB 700. A second portion of the sub-sized PCB 780 may comprise all metal traces for routings and connections to a common ground for supporting circuit die 2. The tall solder ball 785, which can be made with or without high liquidus metal core, are configured to couple between the top surface of main PCB 600 and a second portion of sub-sized PCB 780 to provide electrical connections required for supporting circuit Die 1 or 2.

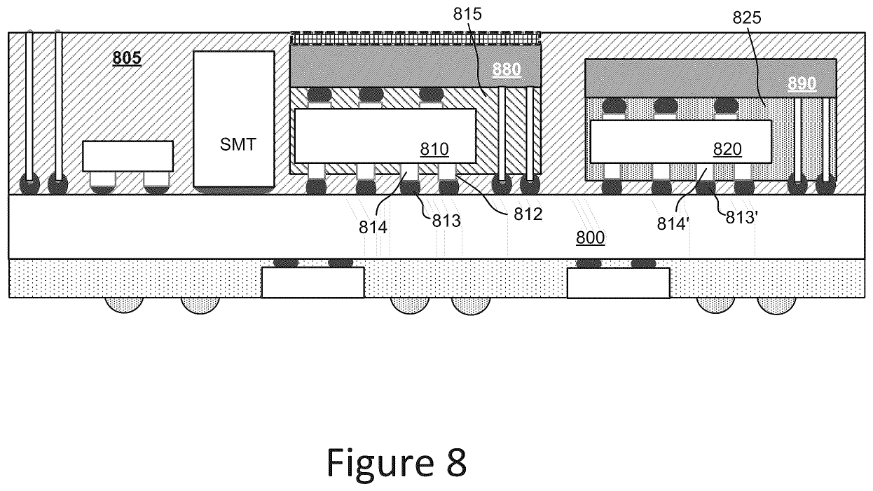

FIG. 8 is a simplified diagram to illustrate a double-sided semiconductor module according to further another embodiment of the present invention. This diagram is merely an example, which should not unduly limit the scope of the claims. One of ordinary skill in the art would recognize many variations, alternatives, and modifications. In the embodiment, the double-sided semiconductor module is packaged substantially the same as the double-sided semiconductor module shown in FIG. 2. In particular, circuit 810 is provided as a double-sided fanout die with its top surface coupled to a bottom surface of a sub-sized PCB 880 and its bottom surface coupled to top surface of a main PCB 800. Circuit 810 is enclosed by an EMC material 815 which includes a recessed region 812. The recessed region 812 around conductor post 814 can be formed as a fully recessed area between two neighbor posts by using plasma etch technique. Or the recessed region 812 can be partially recessed around each post by using laser ablation technique. The recessed region 812 allows extra spacings of the conductor posts 814 to be exposed (sticking out of the mold of EMC material 815). After assembling such circuit block including recessed regions 812 for conductor posts at bottom surface of circuit 810, the conductor posts 814 and conductor joints 813 are bound to the top surface of main circuit board 800, leaving extra rooms below the EMC material 815 around each connection spot. When applying filling material 805 for enclosing all components on the top surface of main circuit board 800, those extra rooms can make a better EMC material filling to secure mold the post/joint pairs. Optionally, another circuit 820 is provided as a double-sided fanout die with its top surface coupled to a bottom surface of another sub-sized PCB 890 and its bottom surface coupled to the top surface of main PCB 800. Circuit 820 is enclosed by another EMC material 825 which is applied during its own circuit block process and leaves no recessed regions except just exposing tips of the conductor posts 814′. While the solder joints 813′ for bounding the conductor posts 814′ still have a height of about 15 um, the EMC material 805 can still be filled in with slightly poor filling. Yet, cost saving is associated with less work in circuit block process.

In some embodiments, as suggested in process flow given in FIG. 3, the circuits mounted between two circuit boards are double-sided bumped and metallized fanout dies. The conductor posts on the circuits in the form of double-sided fanout dies are molded and grinded before mounting to the main PCB, thus the conductor posts have a flat surface profile. According to some embodiments in this disclosure, doubled-sided fanout dies are stacked with sub-PCBs, resulting in a smaller module without increasing module height. The main PCB layer count could potentially be reduced, resulting in module height reduction in z direction. In some embodiments, routings/grounding in sub-PCBs can be placed closer to double-sided dies as needed, which reduces the impedance and improves the electrical performance. In some specific embodiments, the total routing area of sub-PCB and main PCB can be increased, for example, 10% of the main PCB area is moved into sub-PCBs, while main PCB area is reduced by 5%, so the total routing area of the main and sub PCBs is increased while package size is reduced, which provides additional spacing for routing and/or grounding, thus improves the electrical/RF performance. In some other embodiments, SMT components can remain their original sizes and heights, providing improved RF performance with higher Q value, which is a key for achieving high functionality. Otherwise, shorter/smaller components lead to Q value decrease thus compromised RF performance. In another embodiment, flip-chip dies and SMT components can remain their original spacing in x and y directions, which provides improved RF performance due to minimized crosstalk.

While the above is a full description of the specific embodiments, various modifications, alternative constructions and equivalents may be used. Therefore, the above description and illustrations should not be taken as limiting the scope of the present invention which is defined by the appended claims.

What is claimed is:

1. A semiconductor device comprising:
a first circuit board comprising a first top surface and a first bottom surface separated by a first thickness, the first top surface being characterized by a first area;
a first circuit coupled to the first top surface of the first circuit board, the first circuit being characterized by a first height from the first top surface;
a second circuit board comprising a second top surface and a second bottom surface separated by a second thickness, the second bottom surface being characterized by a second area and positioned at a second height opposing to the first top surface, the second top surface being farther from the first top surface than the second bottom surface, the second area being smaller than the first area, the second circuit board comprising a first conductor electrically coupled to the first circuit board;
a second circuit comprising a third top surface and a third bottom surface separated by a third thickness, the third bottom surface being coupled to the first top surface in the first area of the first circuit board, the third top surface being opposite to the third bottom surface and coupled to the second bottom surface in the second area of the second circuit board;
a first filling material comprising a third height from the first top surface to overlay the first circuit and the second circuit board with spacing above the second top surface;
and a second filling material enclosing the first conductor and the second circuit.

2. The semiconductor device of claim 1, further comprising:
a third circuit board comprising a fourth top surface and a fourth bottom surface separated by a fourth thickness, the fourth bottom surface being characterized by a third area and positioned at a fourth height facing the first top surface, the fourth top surface being farther from the first top surface than the fourth bottom surface, the third area plus the second area being smaller than the first area, the third circuit board comprising a second conductor electrically coupled to the first circuit board;
a third circuit comprising a fifth top surface and a fifth bottom surface separated by a fifth thickness, the fifth bottom surface being coupled to the first top surface in the first area of the first circuit board, the fifth top surface being opposite to the fifth bottom surface and coupled to the fourth bottom surface in the third area of the third circuit board; and
a third filling material enclosing the second conductor and the third circuit.

3. The semiconductor device of claim 1, wherein the second circuit board comprises four layers with a total thickness being the second thickness of 100 um or less, the four layers comprising signal paths and routings that at least connect various electrical components of the second circuit to the first circuit board or to a common ground.

4. The semiconductor device of claim 1, wherein the first circuit board comprises 9 layers with a total thickness being the first thickness of 270 um or less.

5. The semiconductor device of claim 1, wherein the first circuit comprises a surface mount technology device with the first height up to 295 um.

6. The semiconductor device of claim 1, wherein the second circuit comprises a double-sided fanout die with the third thickness of 140 um or less.

7. The semiconductor device of claim 1, wherein the second circuit comprises a pre-stacked chip characterized by a total thickness no greater than the third thickness.

8. The semiconductor device of claim 1, wherein the second circuit comprises a conductor post having a height of 25 um disposed on the third bottom surface, the conductor post being configured to couple to a solder joint having a height of 15 um disposed either on the first top surface in the first area of the first circuit board or on top of the conductor post.

9. The semiconductor device of claim 1, wherein the second circuit comprises a conductor pad having a thickness of 5 um disposed on the third top surface, the conductor pad being configured to couple to a solder joint having a height of 15 um either disposed on the second front surface in the second area of the second circuit board or on top of the conductor pad.

10. The semiconductor device of claim 1, wherein the first conductor comprises a length equal to the second height, comprising one or more types selected from vertical wires, tall conductor posts, vias filled with a conducting material, and solder joints with or without high liquidus metal core.

11. The semiconductor device of claim 4, wherein the second circuit board comprises a carrier with a thickness of 30 um after grinding disposed to the second top surface, the carrier comprising a top surface leveling with the third height of the first filling material.

12. The semiconductor device of claim 11, further comprising:
a fourth circuit packaged as a single-sided flip-chip die coupled to the first top surface of the first circuit board;
a fifth circuit packaged as a single-sided flip-chip die coupled to the first bottom surface of the first circuit board;
a fourth filling material comprising a fifth height of 70 um or less from the first bottom surface to a sixth bottom surface to embed the fifth circuit;
multiple conducting contacts configured as input/output ports with a height of 5 um disposed on the sixth bottom surface; and
multiple conductor wires coupled to the first top surface of the first circuit board extending through the first filling material, the multiple conductor wires being used for compartment shielding.

13. The semiconductor device of claim 2, wherein the third circuit board comprises signal paths and routings that at least connect various electrical components of the third circuit to a common ground within the third area in the fourth thickness.

14. The semiconductor device of claim 2, wherein third circuit board and the second circuit board are two portions of one bigger circuit board characterized by a fourth area and the second thickness.

15. The semiconductor device of claim 14, wherein the one bigger circuit board comprises signal paths and routings that at least connect various electrical components of both the second circuit and the third circuit to a common ground within the fourth area in the second thickness.

16. A semiconductor device comprising:
a first circuit board comprising a first top surface and a first bottom surface separated by a first thickness, the first top surface being characterized by a first area;
a first circuit coupled to the first top surface of the first circuit board, the first circuit being characterized by a first height from the first top surface;
a second circuit board comprising a second top surface and a second bottom surface separated by a second thickness, the second bottom surface being characterized by a second area and positioned at a second height opposing to the first top surface, the second area being smaller than the first area, the second height plus the second thickness being about the same as the first height;
a second circuit comprising a third top surface and a third bottom surface separated by a third thickness, the third bottom surface being coupled to the first top surface in the first area of the first circuit board and the third top surface being coupled to the second bottom surface in the second area of the second circuit board;
a third circuit comprising a fourth top surface and a fourth bottom surface separated by a fourth thickness, the second bottom side being coupled to the first top surface in the first area of the first circuit board and the second top side being coupled to the second bottom surface in the second area of the second circuit board;
a first mold comprising a third height from the first top surface to enclose the first circuit and the second circuit board with a spacing above the second top surface;
a second mold comprising the second height from the second bottom surface to enclose the second circuit and the third circuit; and
a through-mold via filled by a conductive material configured to pass through the second mold to electrically couple the second circuit board to the first circuit board.

17. The semiconductor device of claim 16, wherein the second circuit board comprising signal paths and routings that at least connect various electrical components of both the second circuit and the third circuit to a common ground within the second area in the second thickness to allow the first circuit board to be reduced by a size of at least a part of the second area.

18. The semiconductor device of claim 16, wherein the third thickness and the fourth thickness comprise different values under a condition that a sum of the third thickness plus heights of some coupling structures for coupling the second circuit to the first circuit board and the second circuit board, or a sum of the fourth thickness plus heights of some coupling structures for coupling the third circuit to the first circuit board and the second circuit board, remains to be the second height.

19. A semiconductor device comprising:
a first circuit board comprising a first top surface and a first bottom surface separated by a first thickness, the first top surface being characterized by a first area;
a first circuit comprising a surface-mount interface coupled to the first top surface in a third portion of the first area of the first circuit board, the first circuit being characterized by a first height from the first top surface;
a second circuit comprising a first chip coupled to a second circuit board, the first chip comprising a second top surface and a second bottom surface characterized by a second thickness, the second circuit board comprising a third top surface and a third bottom surface separated by a third thickness, the third top surface being attached with a carrier, the third bottom surface being characterized by a second area and being positioned at a second height from the first top surface, the second top surface comprising a first plurality of conductor pads coupled to the third bottom surface in the second area of the second circuit board, the second circuit being coupled to the first circuit board by having a first plurality of conductor posts on the third bottom surface to couple with the first top surface in a first portion of the first area of the first circuit board;
a second filling material enclosing the first chip on the second circuit board entirely except first recessed regions to expose the first plurality of conductor posts;
a third circuit comprising a second chip coupled to a third circuit board, the second chip comprising a fourth top surface and a fourth bottom surface characterized by a fourth thickness, the third circuit board comprising a fifth top surface and a fifth bottom surface separated by a fifth thickness, the fifth bottom surface being characterized by a third area and being positioned at a third height from the first top surface, the fourth top surface comprising a second plurality of conductor pads coupled to the third bottom surface in the third area of the third circuit board, the third circuit being coupled to the first circuit board by having a second plurality of conductor posts on the fourth bottom surface to couple with the first top surface in a second portion of the first area of the first circuit board;
a third filling material enclosing the second chip on the third circuit board except second recessed regions to expose the second plurality of conductor posts; and
a first filling material enclosing the first circuit and the third circuit block while leveling with a top surface of the carrier attached to the third top surface of the second circuit, the first filling material filling the first recessed regions and the second recessed regions.

20. The semiconductor device of claim 19, wherein:
the first circuit board comprises 9 layers or less characterized by a total thickness of 270 um or less;
the second circuit board comprises 4 layers characterized by a total thickness of 100 um or less;
the first filling material comprises a fourth height over the fifth top surface of the third circuit by a spacing of 50 um or less;
the carrier comprises a minimum thickness of 30 um;
each of the first and second plurality of conductor posts comprises a length of 25 um after grinding;
each of the first and second plurality of conductor pads comprises a height of 5 um;
each of the third thickness and the fourth thickness comprises a value of 140 um or less; and
the first height comprises a value up to 295 um or less.
